(19) United States
(12) Patent Application Publication
(10) Pub. No.: US 2026/0351157 A1
(43) Pub. Date: Nov. 5, 2026

(54) DISPLAY DEVICE, ELECTRONIC DEVICE INCLUDING THE SAME, AND DRIVING METHOD OF DISPLAY DEVICE

(71) Applicant: Samsung Display Co., Ltd., Yongin-Si (KR)

(72) Inventors: Kuk-Hwan AHN, Yongin-si (KR); Kyungsu LEE, Yongin-si (KR); DAE-GWANG JANG, Yongin-si (KR)

(21) Appl. No.: 19/633,236

(22) Filed: Mar. 30, 2026

(30) Foreign Application Priority Data
Apr. 30, 2025 (KR) 10-2025-0057096

(51) Int. Cl. G09G 3/20; G09G 3/00; H10K 59/80; G09G 3/3208

(52) U.S. Cl. CPC G09G 3/2092; G09G 3/035; G09G 3/2007; H10K 59/8794; G09G 3/3208; G09G 2320/041

(57) ABSTRACT

A heat generation data calculation unit of a display device includes an average area setting unit that sets pixel areas to average areas having average grayscales of the pixel areas, a diffusion area setting unit that sets temperature values of blocks of diffusion areas based on the average grayscales, and a lookup table map generation unit that sums temperature values of blocks overlapping each other to produce summed temperature values of the blocks overlapping each other, and outputs the summed temperature values. A diffusion area disposed in a folding area and a non-folding area of the display panel is defined as an overlapping diffusion area, and the diffusion area setting unit reduces temperature values of first blocks of the overlapping diffusion area disposed in the non-folding areas by a reduction rate.

### CROSS-REFERENCE TO RELATED APPLICATIONS

This U.S. non-provisional patent application claims priority under 35 U.S.C. §119 to Korean Patent Application No. 10-2025-0057096, filed on Apr. 30, 2025, in the Korean Intellectual Property Office, the entire contents of which are hereby incorporated by reference.

### BACKGROUND

The present disclosure relates to a display device, a driving method thereof, and an electronic device including the display device.

Electronic devices such as smartphones, digital cameras, notebook computers, navigation systems, and smart television include display devices to display images to users. The display devices generate the images and provide the images to the users through display screens.

A display device includes a display panel that includes a plurality of pixels that generate an image, a driving unit that drives the pixels, and a controller that controls an operation of the driving unit. The pixels are driven by the driving unit to generate the image.

When the pixels emit light with a predetermined luminance, the display panel may be heated. The display panel may be further heated in a portion with high luminance. When a temperature of the display panel rises, elements of the pixels may deteriorate. When the elements deteriorate, the pixels may not emit light with normal luminance. Therefore, there is a need to develop a technique for compensating for a heat generation state of the pixels.

### SUMMARY

The present disclosure provides a display device capable of calculating a heat generation data calculated based on grayscales of pixels to be suitable for a non-folding area and a folding area of a display panel, an electronic device including the same, and a driving method of the display device.

According to an embodiment, a display device includes a display panel including a plurality of pixels and a timing controller that controls driving of the pixels and includes a heat generation data calculation unit, the heat generation data calculation unit includes an average area setting unit that sets a plurality of pixel areas, each of which includes some pixels among the pixels, and sets the pixel areas to a plurality of average areas having average grayscales of the pixel areas, respectively, a diffusion area setting unit that sets a plurality of diffusion areas, each of which includes a plurality of blocks, and sets temperature values of the blocks of the diffusion areas based on the average grayscales, and a lookup table map generation unit that sums temperature values of blocks of the diffusion areas overlapping each other to produce summed temperature values of the blocks overlapping each other, and outputs the summed temperature values. A diffusion area disposed in a folding area and a non-folding area of the display panel is defined as an overlapping diffusion area, and the diffusion area setting unit reduces temperature values of first blocks disposed in the non-folding areas among blocks of the overlapping diffusion area by a predetermined reduction rate.

According to an embodiment, a driving method of a display device includes setting a plurality of pixel areas, each of which includes some pixels among pixels of a display panel, setting the pixel areas to a plurality of average areas having average grayscales of the pixel areas, respectively, setting a plurality of diffusion areas, each of which includes a plurality of blocks, setting temperature values of the blocks of the diffusion areas based on the average grayscales, reducing temperature values of first blocks disposed in a non-folding area among blocks of an overlapping diffusion area by a predetermined reduction rate, the overlapping diffusion area defined as a diffusion area disposed in a folding area and the non-folding area of the display panel, increasing temperature values of second blocks disposed in the folding area to be symmetrical to the first blocks among the blocks of the overlapping diffusion area, summing temperature values of blocks of the diffusion areas overlapping each other to produce summed temperature values of the blocks overlapping each other, outputting the summed temperature values of the blocks overlapping each other, and compensating, based on the temperature values, image data obtained by converting image signals received to be provided to the pixels. The second blocks are arranged to be respectively symmetrical to the first blocks with respect to a boundary between the folded area and the non-folded area.

According to an embodiment, an electronic device includes a processor and a display device that receives image signals from the processor and provides images corresponding to the image signals to a user, the display device includes a display panel including a plurality of pixels and a timing controller that controls driving of the pixels and includes a heat generation data calculation unit. The heat generation data calculation unit includes an average area setting unit that sets a plurality of pixel areas, each of which includes some pixels among the pixels, and sets the pixel areas to a plurality of average areas having average grayscales of the pixel areas, respectively, a diffusion area setting unit that sets a plurality of diffusion areas, each of which includes a plurality of blocks, and sets temperature values of the blocks of the diffusion areas based on the average grayscales, and a lookup table map generation unit that sums temperature values of blocks of the diffusion areas overlapping each other to produce summed temperature values of the blocks overlapping each other, and outputs the summed temperature values of the blocks overlapping each other. A diffusion area disposed in a folding area and a non-folding area of the display panel is defined as an overlapping diffusion area, and the diffusion area setting unit reduces temperature values of first blocks disposed in the non-folding areas among blocks of the overlapping diffusion area by a predetermined reduction rate.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a block diagram of the electronic device according to the embodiment of the present disclosure;

FIG. 2 is a schematic view of various electronic devices according to embodiments of the present disclosure;

FIG. 3 is a perspective view of the electronic device according to an embodiment of the present disclosure;

FIG. 4 is a view illustrating a folded state of the electronic device shown in FIG. 3;

FIG. 5 is an exploded perspective view of the electronic device shown in FIG. 3;

FIG. 6 is a cross-sectional view of the display device shown in FIG. 5;

FIG. 7 is a cross-sectional view of the display panel shown in FIG. 6;

FIG. 8 is a block diagram of the display device shown in FIG. 5;

FIG. 9 is a plan view of the display panel shown in FIG. 8;

FIG. 10 is a block diagram of the heat generation data calculation unit shown in FIG. 8;

FIG. 11 is a view exemplarily illustrating images displayed in the display area of the electronic device;

FIG. 12 is a view illustrating the first pixel area shown in FIG. 11;

FIG. 13 is a view illustrating first to fourth average areas corresponding to the first to fourth pixel areas shown in FIG. 11;

FIG. 14 is a view illustrating a first diffusion area corresponding to the first average area shown in FIG. 13;

FIG. 15 is a view illustrating a second diffusion area corresponding to the second average area shown in FIG. 13;

FIG. 16 is a view illustrating a third diffusion area corresponding to the third average area shown in FIG. 13;

FIG. 17 is a view illustrating a summing operation of temperature values of the first, second, and third diffusion areas shown in FIGS. 14-16.

FIG. 18 is a view illustrating summed values of the temperature values shown in FIG. 17;

FIGS. 19 and 20 are views illustrating an operation of the diffusion area setting unit when the center block is disposed in the folding area of the display panel; and

FIG. 21 is a flowchart illustrating a method of driving a display according to the embodiment of the present disclosure.

### DETAILED DESCRIPTION

In this specification, it will be understood that when an element (or a area, a layer, a portion, or the like) is referred to as being "on", "connected to" or "coupled to" another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents.

It will be understood that, although the terms “first”, “second”, etc. may be used herein to describe various elements, the elements are not to be limited by these terms. These terms are only used to distinguish one element, component, area, layer or section from another element, component, area, layer or section. For instance, a first element, component, area, layer or section discussed below could be termed a second element, component, area, layer or section without departing from the scope of the inventive concept. Similarly, a second element, component, area, layer or section could be termed a first element, component, area, layer or section. In this specification, the singular expressions "a", "an" and "the" are intended to include the plural forms as well, unless the context clearly indicates otherwise.

In addition, the terms "below", “under”, "on the lower side", "above", “over”, "on the upper side", or the like may be used to describe the relationships between the elements illustrated in the drawings. These terms are relative concepts and are described on the basis of the directions indicated in the drawings.

It will be further understood that the terms "comprises, includes, has" as well as "comprising, including, having", when used in this specification, specify the presence of stated features, numbers, steps, operations, elements, components or combinations thereof, but do not preclude the possibility of the presence or addition of one or more other features, numbers, steps, operations, elements, components, or combinations thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to accompanying drawings.

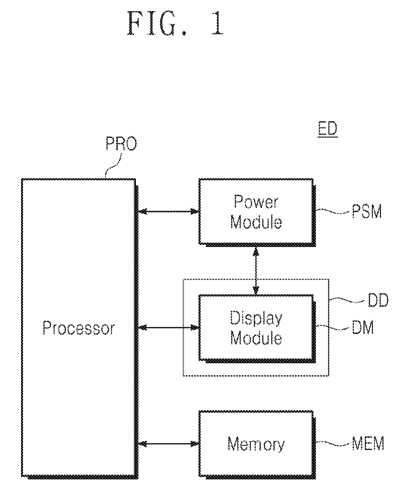

FIG. 1 is a block diagram of the electronic device according to the embodiment of the present disclosure.

Referring to FIG. 1, the electronic device ED according to the present disclosure may include a display device DD and may further include modules or devices having additional functions in addition to the display device DD. The electronic device ED may include a display module DM, a processor PRO, a memory MEM, and a power module PSM, and the display device DD may include the display module DM.

The processor PRO may include at least one of a central processing unit (CPU), an application processor (AP), a graphics processing unit (GPU), a communication processor (CP), an image signal processor (ISP), and a controller.

The processor PRO may process image signals and provide the processed image signals to the display device DD. The display device DD may receive the image signals from the processor PRO and may display images corresponding to the image signals to a user.

The processor PRO may be electrically connected to the display module DM of the display device DD via a flexible printed circuit board, a connector, and the like. The display module DM may display images based on data received from the processor PRO.

In an embodiment, the processor PRO may be divided into two or more components from a functional or structural perspective. For example, the processor PRO may include a main processor in the form of a first driving chip that includes the central processing unit and an auxiliary processor in the form of a second driving chip that includes the controller configured to receive image signals from the main processor and to process the image signals according to an interface specification of the display module DM.

The memory MEM may store data information required for the operation of the processor PRO or the display module DM. When the processor PRO executes an application stored in the memory MEM, an image signal and an input control signal may be transmitted to the display module DM, and the display module DM may process the received signals to output image information through a display screen.

The power module PSM may include a power supply module, such as a power adapter or a battery device, and a power conversion module that converts power supplied by the power supply module to generate power required for the operation of the electronic device ED.

At least one of components of the electronic device ED may be included in the display device DD. In addition, among individual modules that are functionally included within a single module, some may be included in the display device DD while others may be provided separately from the display device DD. As an example, the display device DD may include the display module DM, and the processor PRO, the memory MEM, and the power module PSM may be provided as separate devices within the electronic device ED without being included in the display device.

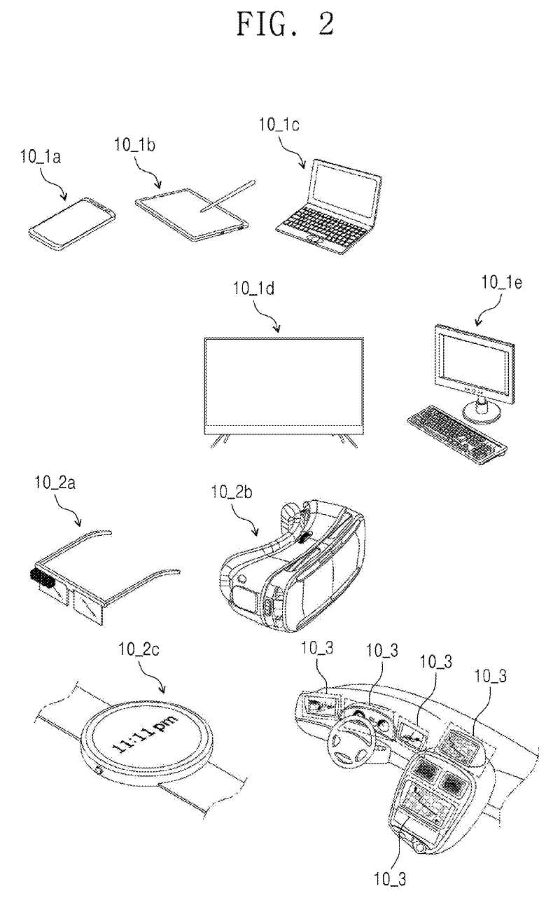

FIG. 2 is a schematic view of various electronic devices according to embodiments of the present disclosure.

Referring to FIG. 2, the display device DD according to the present disclosure may be applied to various electronic devices. As an example, various electronic devices to which the display device DD according to embodiments is applied may include an electronic device to display images, such as a smartphone 10_1a, a tablet PC 10_1b, a laptop computer 10_1c, a television 10_1d, a desktop monitor 10_1e, etc.

In addition, various electronic devices to which the display device DD according to embodiments is applied may include wearable electronic devices, such as a smart glasses 10_2a, a head-mounted display 10_2b, a smartwatch 10_2c, etc. Further, various electronic devices to which the display device DD according to embodiments is applied may include an in-vehicle electronic device 10_3, such as an instrument panel, a center fascia, a dashboard-mounted center information display (CID), or a room mirror display.

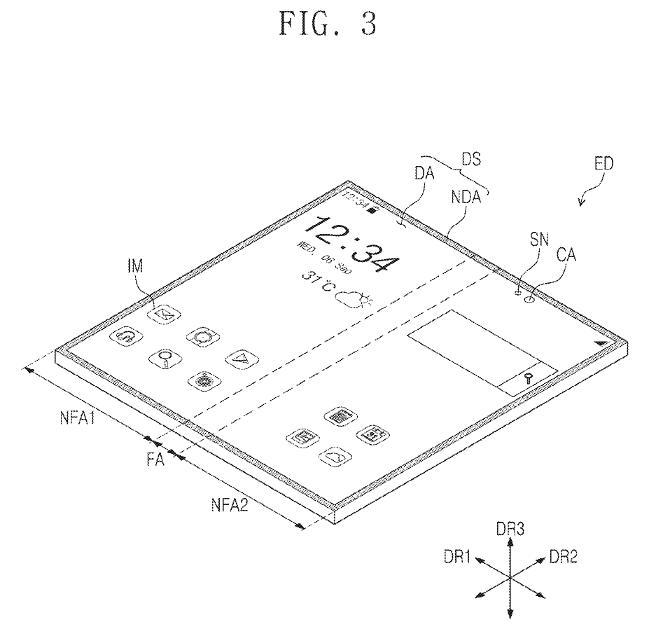

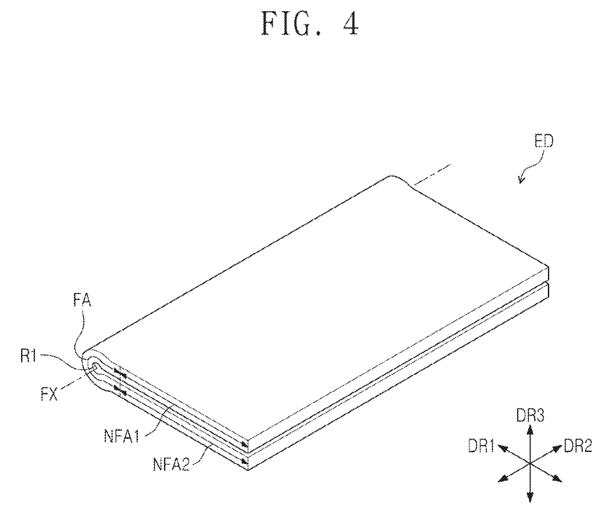

FIG. 3 is a perspective view of the electronic device according to an embodiment of the present disclosure. FIG. 4 is a view illustrating a folded state of the electronic device shown in FIG. 3.

As an example, the electronic device ED shown in FIGS. 3 and 4 may be a foldable smartphone.

Referring to FIG. 3, the electronic device ED may include a plane defined by a first direction DR1 and a second direction DR2 intersecting the first direction DR1. When viewed in a plane, the electronic device ED may have a quadrangular shape. However, the shape of the electronic device ED should not be limited to the rectangular shape, and the electronic device ED may have various shapes, such as a circular shape and a polygonal shape. The electronic device ED may be a flexible electronic device.

Hereinafter, a direction substantially perpendicular to the plane defined by the first direction DR1 and the second direction DR2 may be referred to as a third direction DR3. In the present disclosure, the expression “when viewed in a plane” may mean a state of being viewed in the third direction DR3.

The electronic device ED may include a folding area FA and a plurality of non-folding areas NFA1 and NFA2. The non-folding areas NFA1 and NFA2 may include a first non-folding area NFA1 and a second non-folding area NFA2. The folding area FA may be disposed between the first non-folding area NFA1 and the second non-folding area NFA2. The first non-folding area NFA1, the folding area FA, and the second non-folding area NFA2 may be arranged in the first direction DR1.

In the present embodiment, one folding area FA and two non-folding areas NFA1 and NFA2 are shown as a representative example, however, the number of the folding areas FA and the number of non-folding areas NFA1 and NFA2 should not be limited thereto or thereby. For example, the electronic device ED may include more than two non-folding areas and a plurality of folding areas disposed between the non-folding areas.

An upper surface of the electronic device ED may be referred to as a display surface DS, and the display surface DS may be a plane defined by the first direction DR1 and the second direction DR2. Images IM generated by the electronic device ED may be provided to a user through the display surface DS.

The display surface DS may include a display area DA and a non-display area NDA around the display area DA. The display area DA may display the image, and the non-display area NDA may not display the image. The non-display area NDA may surround the display area DA and may define an edge of the electronic device ED, which is printed by a predetermined color.

The electronic device ED may include at least one sensor SN and at least one camera CA. The sensor SN and the camera CA may be disposed adjacent to the edge of the electronic device ED. The sensor SN and the camera CA may be disposed in the display area DA adjacent to the non-display area NDA. The sensor SN and the camera CA may be disposed in the second non-folding area NFA2, however, according to an embodiment, the sensor SN and the camera CA may be disposed in the first non-folding area NFA1.

A light may be provided to the camera CA and the sensor SN after passing through portions of the electronic device ED on which the sensor SN and the camera CA are disposed. As an example, the sensor SN may be a proximity illumination sensor, however, the sensor SN should not be particularly limited. The camera CA may take a picture of external objects. Each of the sensor SN and the camera CA may be provided in plural.

Referring to FIG. 4, the electronic device ED may be a foldable electronic device ED that is folded or unfolded. The folding area FA may be folded with respect to a folding axis FX substantially parallel to the second direction DR2, and thus, the electronic device ED may be folded.

When the electronic device ED is folded, the first non-folding area NFA1 and the second non-folding area NFA2 may face each other, and thus, the electronic device ED may be inwardly folded (in-folding) such that the display surface DS is not exposed to the outside. However, the present disclosure should not be limited thereto or thereby. As an example, the electronic device ED may be outwardly folded (out-folding) with respect to the folding axis FX such that the display surface DS is exposed to the outside.

A distance between the first non-folding area NFA1 and the second non-folding area NFA2 may be smaller than a diameter of a circle defined by a radius of curvature R1 of the folding area FA. In this case, the folding area FA may be folded to have a dumbbell shape, and the distance between the first non-folding area NFA1 and the second non-folding area NFA2 may be reduced.

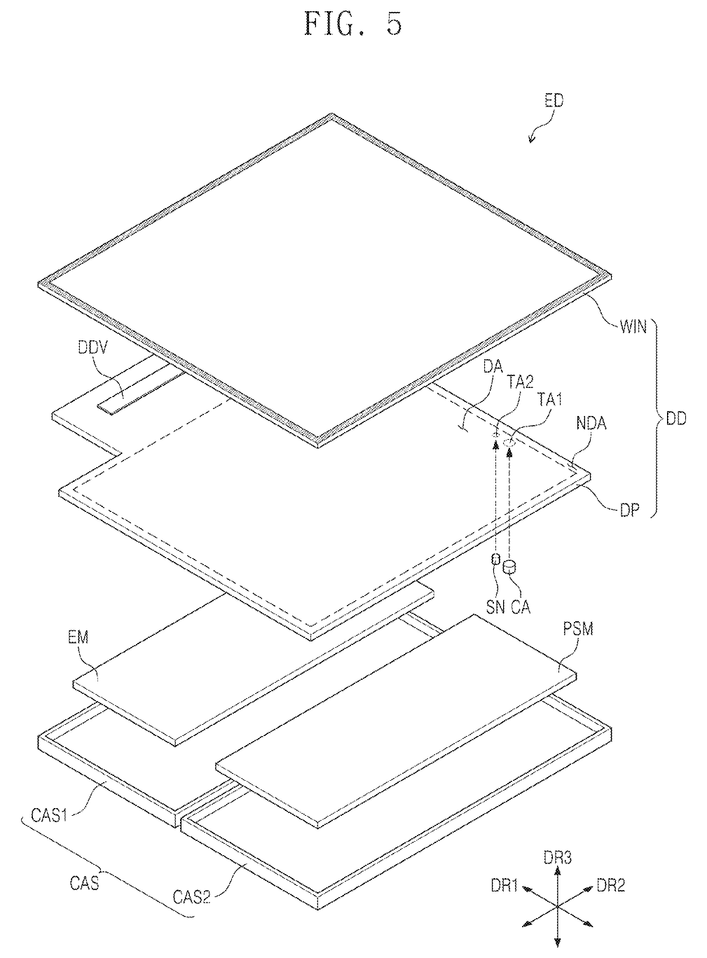

FIG. 5 is an exploded perspective view of the electronic device shown in FIG. 3.

Referring to FIG. 5, the electronic device ED may include the display device DD, the camera CA, the sensor SN, an electronic module EM, the power module PSM, and a case CAS.

The display device DD may include a window WIN and a display panel DP. As an example, FIG. 5 shows the window WIN and the display panel DP among components of the display device DD, however, the display device DD may further include various components in addition to the window WIN and the display panel DP. The detailed stack structure of the display device DD will be described later.

The window WIN may be disposed on the display panel DP and may protect the display panel DP. The window WIN may transmit a light generated by the display panel DP to provide the light to a user.

The display panel DP may include a display area DA and a non-display area NDA, which respectively correspond to the display area DA (refer to FIG. 3) and the non-display area NDA (refer to FIG. 3) of the electronic device ED. A first transmission area TA1 and a second transmission area TA2 may be defined in the display panel DP. The first transmission area TA1 and the second transmission area TA2 may have higher light transmittance than surrounding areas.

The camera CA may be disposed under the first transmission area TA1, and the sensor SN may be disposed under the second transmission area TA2. The light transmitted through the first and second transmission areas TA1 and TA2 may be provided to the camera CA and the sensor SN.

The display device DD may include a data driver DDV disposed in the non-display area NDA of the display panel DP. The data driver DDV may be manufactured in an integrated circuit chip form and may be mounted on the non-display area NDA, however, it should not be limited thereto or thereby. According to an embodiment, the data driver DDV may be mounted on a flexible circuit board connected to the display panel DP.

The electronic module EM and the power module PSM may be disposed under the display device DD. Although not shown in figures, the electronic module EM and the power module PSM may be connected to each other via a separate flexible circuit board. The electronic module EM may control an operation of the display device DD. The power module PSM may supply a power to the electronic module EM. The electronic module EM may include the processor PRO.

The case CAS may accommodate the display device DD, the electronic module EM, and the power module PSM. The case CAS may include two cases, e.g., first and second cases CAS1 and CAS2, to fold the display device DD. The first and second cases CAS1 and CAS2 may extend in the second direction DR2 and may be arranged in the first direction DR1.

Although not shown in figures, the electronic device ED may further include a hinge structure to connect the first and second cases CAS1 and CAS2 and to rotate the first and second cases CAS1 and CAS2 such that the electronic device ED is folded. The case CAS may protect the display device DD, the electronic module EM, and the power module PSM.

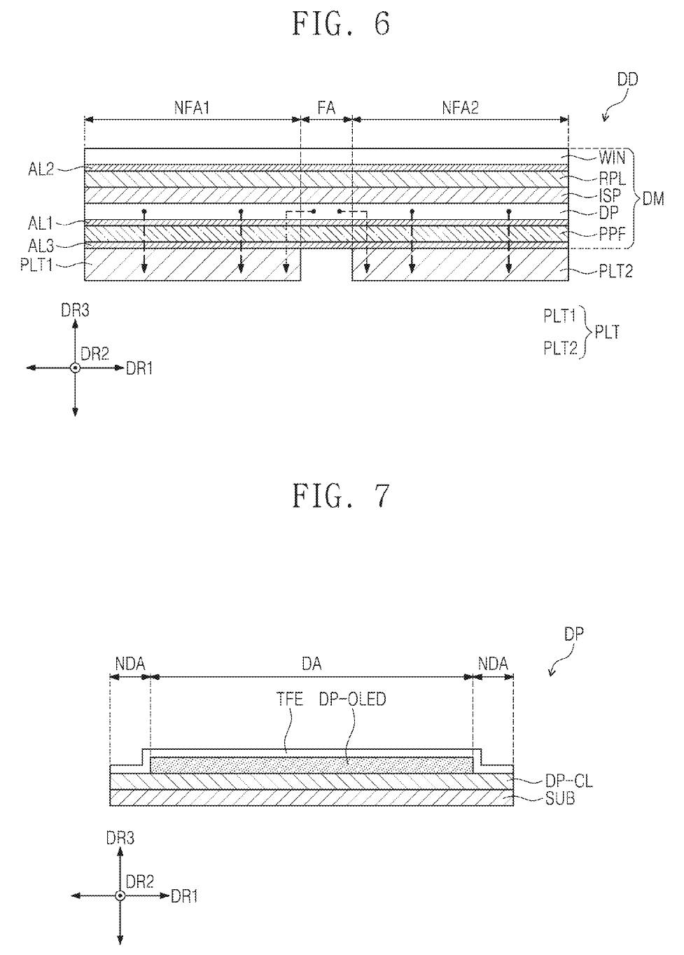

FIG. 6 is a cross-sectional view of the display device shown in FIG. 5.

As an example, FIGS. 6 show the cross section of the display device DD when viewed in the second direction DR2

Referring to FIG. 6, the display device DD may include a display module DM and a support plate PLT disposed under the display module DM. The display module DM may include a display panel DP, an input sensing part ISP, a reflection prevention layer RPL, a window WIN, a panel protective film PPF, and first, second, and third adhesive layers AL1, AL2, and AL3.

According to an embodiment, the display panel DP may be a light emitting type display panel. As an example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot or a quantum rod. Hereinafter, the organic light emitting display panel will be described as a representative example of the display panel DP.

The display panel DP may include a folding area FA and first and second non-folding areas NFA1 and NFA2, respectively, corresponding to the folding area FA and the first and second non-folding areas NFA1 and NFA2 of the electronic device ED. Accordingly, the first and second non-folding areas NFA1 and NFA2 may be adjacent to the folding area FA in the first direction DR1, and the folding area FA may be disposed between the first and second non-folding areas NFA1 and NFA2. The first non-folding area NFA1, the folding area FA, and the second non-folding area NFA2 may be arranged in the first direction DR1.

The input sensing part ISP may be disposed on the display panel DP. The input sensing part ISP may include a plurality of sensing parts (not illustrated) for sensing an external input in a capacitive manner. When the display device DD is manufactured, the input sensing part ISP may be directly manufactured on the display panel DP. However, the present disclosure is not limited thereto, and the input sensing part ISP may be manufactured as a separate panel from the display panel DP and be attached to the display panel DP by an adhesive layer.

The reflection prevention layer RPL may be disposed on the input sensing part ISP. When the display device DD is manufactured, the reflection prevention layer RPL may be directly manufactured on the input sensing part ISP. However, the present disclosure is not limited thereto, and the reflection prevention layer RPL may be manufactured as a separate panel, and may be attached to the input sensing part ISP by an adhesive layer.

The reflection prevention layer RPL may be defined as an external light reflection prevention film. The reflection prevention layer RPL may reduce a reflectance of external light that is input from a top surface of the display device DD toward the display panel DP. The external light may not be visually recognized by a user due to the reflection prevention layer RPL.

When external light directed toward the display panel DP is reflected from the display panel DP and is provided again to an external user, the user may visually recognize the external light, like a mirror. To prevent this phenomenon, the reflection prevention layer RPL may include a plurality of color filters for displaying the same colors as those of the pixels of the display panel DP.

The color filters may filter the external light to the same colors as those of the pixels. In this case, the external light may not be visually recognized by the user. However, the present disclosure is not limited thereto, and the reflection prevention layer RPL may include a phase retarder or a polarizer to reduce the reflectance of the external light.

The window WIN may be disposed on the reflection prevention layer RPL. The window WIN may protect the display panel DP, the input sensing part ISP, and the reflection prevention layer RPL from external scratches and impacts.

The panel protective film PPF may be disposed under the display panel DP. The panel protective film PPF may protect a lower side of the display panel DP. The panel protective film PPF may include a flexible plastic material such as Polyethyleneterephthalate (PET).

The first adhesive layer AL1 may be disposed between the display panel DP and the panel protective film PPF, and the display panel DP and the panel protective film PPF may be bonded to each other by the first adhesive layer AL1. The second adhesive layer AL2 may be disposed between the window WIN and the reflection prevention layer RPL, and the window WIN and the reflection prevention layer RPL may be bonded to each other by the second adhesive layer AL2.

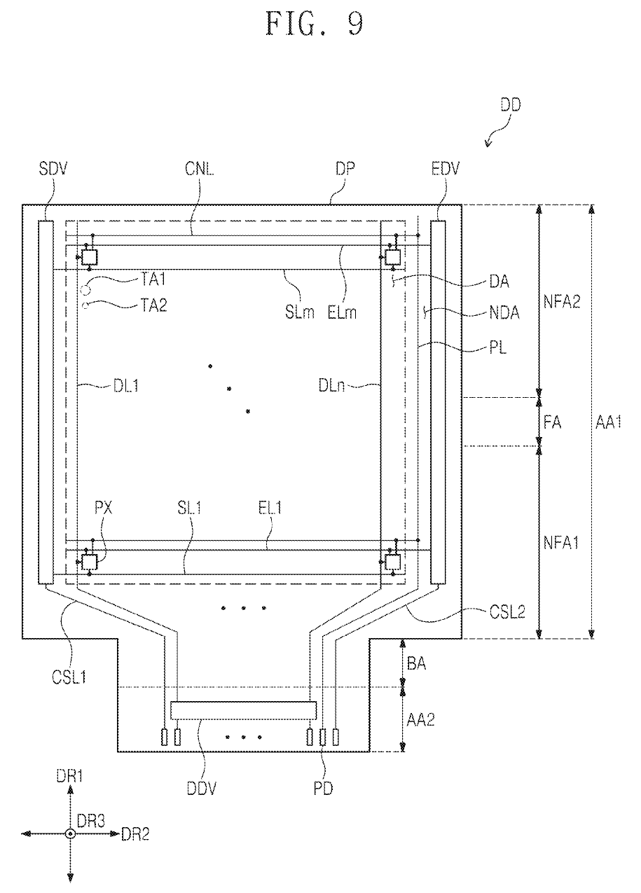

The support plate PLT may be disposed under the panel protective film PPP. The support plate PLT may support the display module DM. The support plate PLT may include a metal. The support plate PLT may perform a heat dissipation function. For example, the display panel DP includes a plurality of pixels (hereinafter, shown in FIGS. 8 and 9), and when the pixels of the display panel DP are driven to display images, heat generated in the display panel DP may be emitted through the support plate PLT.

The support plate PLT may include a first support plate PLT1 and a second support plate PLT2 disposed under the panel protective film PPP and spaced apart from each other in the first direction DR1. When viewed in a plane, the first support plate PLT1 may overlap the first non-folding area NFA1, and the second support plate PLT2 may overlap the second non-folding area NFA2. When viewed in a plane, the first support plate PLT1 and the second support plate PLT2 may not overlap the folding area FA.

The third adhesive layer AL3 may be disposed between the first support plate PLT1 and the panel protective film PPF and between the second support plate PLT2 and the panel protective film PPF. The first support plate PLT1 and the panel protective film PPF may be bonded to each other by the third adhesive layer AL3. The second support plate PLT2 and the panel protective film PPF may be bonded to each other by the third adhesive layer AL3. The third adhesive layer AL3 may not be disposed below the folding area FA.

When a more rigid support plate PLT is disposed under the folding area FA and attached to the panel protective film PPF, a folding operation of the folding area FA may be difficult. Since the support plate PLT is not disposed under the folding area FA, the folding operation of the folding area FA may be easily performed.

When pixels of the display panel DP are driven, heat may be generated. As an example, the heat generated in the display panel DP is indicated by circular dots in FIG. 6, and an emission direction of the heat is shown by a dotted arrow.

The heat generated in each of the first and second non-folding areas NFA1 and NFA2 of the display panel DP may be transferred to the first and second support plates PLT1 and PLT2 disposed under the first and second non-folding areas NFA1 and NFA2. The heat generated in each of the first and second non-folding areas NFA1 and NFA2 may be directly transferred to the first and second support plates PLT1 and PLT2 to be easily released by the first and second support plates PLT1 or PLT2.

The heat generated in the folding area FA of the display panel DP may not be discharged under the folding area FA because the support plate PLT is not disposed under the folding area FA. Therefore, the heat generated in the folding area FA may be transferred to the first and second support plates PLT1 and PLT2 via the first and second non-folding areas NFA1 and NFA2.

In this case, some of the heat generated in the folding area FA may be transferred to the first and second support plates PLT1 and PLT2 via the first and second non-folding areas NFA1 and NFA2, but the remaining heat may remain in the folded area FA. That is, some of the heat generated in the folding area FA may diffuse to the first and second non-folding areas NFA1 and NFA2, but the remaining heat may remain in the folded area FA. Thus, when the pixels are driven, the folding area FA may have a relatively higher temperature than the first and second non-folding areas NFA1 and NFA2. As an example, thicknesses of the dotted lines in FIG. 6 may represent the rate of heat transfer.

In an embodiment of the present disclosure, when a heat generation data of the display panel DP is calculated, the heat generation data may be calculated to be suitable for the first and second non-folding areas NFA1 and NFA2 and the folding area FA, respectively. Such configurations and operations will be described in detail below.

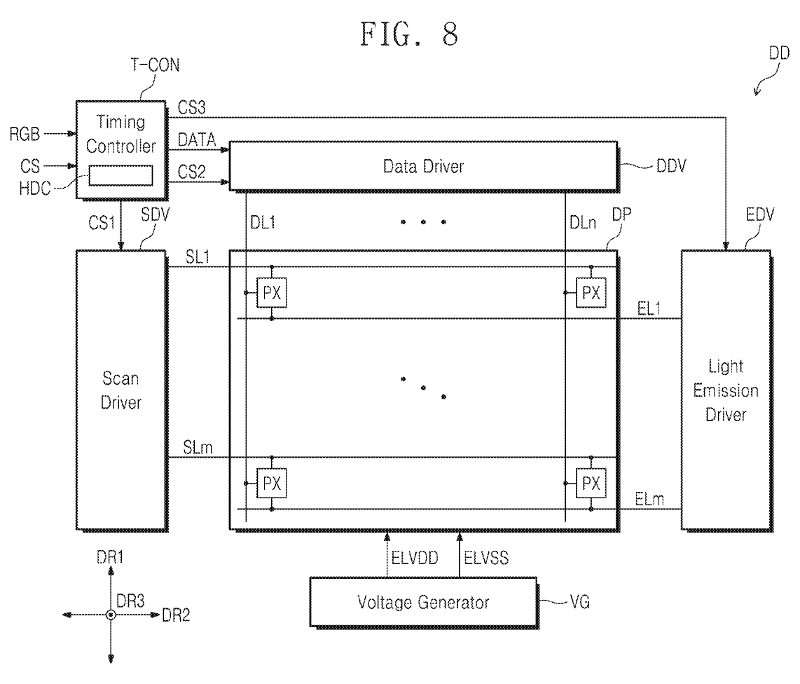

FIG. 7 is a cross-sectional view of the display panel shown in FIG. 6.

As an example, FIG. 7 show the cross section of the display panel DP when viewed in the second direction DR2

Referring to FIG. 7, the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

The substrate SUB may include a display area DA and a non-display area NDA around the display area DA. The substrate SUB may include a glass material or a flexible plastic material such as polyimide (PI). The display element layer DP-OLED may be disposed in the display area DA.

A plurality of pixels may be arranged in the circuit element layer DP-CL and the display element layer DP-OLED. Each pixel may include transistors arranged in the circuit element layer DP-CL and a light emitting element arranged in the display element layer DP-OLED and connected to the transistors.

The thin film encapsulation layer TFE may be disposed on the circuit element layer DP-CL to cover the display element layer DP-OLED. The thin film encapsulation layer TFE may protect the pixels from moisture, oxygen, and a foreign substance.

FIG. 8 is a block diagram of the display device shown in FIG. 5.

Referring to FIG. 8, the display device DD may include a display panel DP, a scan driver SDV, a data driver DDV, a light emission driver EDV, a timing controller T-CON, and a voltage generator VG.

The display panel DP may include a plurality of pixels PX, a plurality of scan lines SL1 to SLm, a plurality of data lines DL1 to DLn, and a plurality of light emission lines EL1 to ELm. Each of “m” and “n” is a natural number.

The scan lines SL1 to SLm may extend in the second direction DR2 and may be connected to the pixels PX and the scan driver SDV. The data lines DL1 to DLn may extend in the first direction DR1 and may be connected to the pixels PX and the data driver DDV. The light emission lines EL1 to ELm may extend in the second direction DR2 and may be connected to the pixels PX and the light emission driver EDV.

A first voltage ELVDD and a second voltage ELVSS having a level lower than the first voltage ELVDD may be applied to the display panel DP. The first voltage ELVDD and the second voltage ELVSS may be applied to the pixels PX.

The timing controller T-CON may receive image signals RGB and a control signal CS from the outside (e.g., a system board). The image signals RGB are signals to be provided to the pixels PX, and the pixels PX may display images corresponding to the image signals RGB. The timing controller T-CON may control operations of the scan driver SDV, the data driver DDV, and the light emitting driver EDV based on the control signal CS.

The image signals RGB may be provided to the pixels PX through the timing controller T-CON and the data driver DDV. For example, a data format of the image signals RGB may be converted by the timing controller T-CON, and the image signals RGB of which the data format is converted may be converted into data voltages by the data driver DDV and provided to the pixels PX.

The timing controller T-CON may generate image data DATA by converting the data format of the image signals RGB to match an interface specification with the data driver DDV. The image data DATA may be defined as the image signals RGB of which data format is converted. The timing controller T-CON may provide the image data DATA to the data driver DDV. The image data DATA may be provided to the pixels PX through the data driver DDV.

The timing controller T-CON may control driving of the pixels PX. For example, the timing controller T-CON may control operations of the scan driver SDV, the data driver DDV, and the light emission driver EDV that drive the pixels PX.

The timing controller T-CON may generate and output a first control signal CS1, a second control signal CS2, and a third control signal CS3 in response to the control signal CS provided from the outside. The first control signal CS1 may be defined as a scanning control signal, the second control signal CS2 may be defined as a data control signal, and the third control signal CS3 may be defined as a light emission control signal. The first control signal CS1 may be provided to the scanning driver SDV, the second control signal CS2 may be provided to the data driver DDV, and the third control signal CS3 may be provided to the light emission driver EDV.

The scan driver SDV may generate a plurality of scan signals in response to the first control signal CS1. The scan signals may be applied to the pixels PX through the scan lines SL1 to SLm. The data driver DDV may generate a plurality of data voltages corresponding to the image data DATA in response to the second control signal CS2. The data voltages may be applied to the pixels PX through the data lines DL1 to DLn. The light emission driver EDV may generate a plurality of light emission signals in response to the third control signal CS3. The light emission signals may be applied to the pixels PX through the light emission lines EL1 to ELm.

Pixels PX may receive data voltages in response to scan signals. The pixels PX may display images by emitting light having a luminance corresponding to the data voltages in response to the light emission signals. The light emission time of the pixels PX may be controlled by the light emission signals.

The voltage generator VG may generate the first voltage ELVDD and the second voltage ELVSS and apply them to the display panel DP. The pixels PX may be driven by the first and second voltages ELVDD and ELVSS.

The timing controller T-CON may include a heat generation data calculation unit HCP. The heat generation data calculation unit HCP may calculate temperature values corresponding to a heat generation state of the display area DA based on the grayscales of the image signals RGB. The operation of the heat generation data calculation unit HCP will be described in detail below.

FIG. 9 is a plan view of the display panel shown in FIG. 8.

FIG. 8 is a view mainly illustrating functional blocks of the display device DD, and FIG. 9 is a view mainly showing a planar structure of the display panel DP.

Referring to FIG. 9, the display device DD may include a display panel DP, a scan driver SDV, a data driver DDV, and a light emission driver EDV.

The display panel DP may include a first area AA1, a second area AA2, and a bending area BA between the first area AA1 and the second area AA2. The first area AA1, the bending area BA, and the second area AA2 may be arranged in the first direction DR1.

The first area AA1 may include the display area DA and the non-display area NDA around the display area DA. The non-display area NDA may surround the display area DA. The display area DA may be an area in which images are displayed, and the non-display area NDA may be an area in which the images are not displayed. The second area AA2 and the bending area BA may be areas in which the images are not displayed.

When viewed in the second direction DR2, the first area AA1 may include a first non-folding area NFA1, a second non-folding area NFA2, and a folding area FA between the first non-folding area NFA1 and the second non-folding area NFA2. The first and second transmission areas TA1 and TA2 may be defined in the display area DA and the second non-folding area NFA2. display area

The first area AA1 may be folded with respect to the folding axis FX. As an example, since the folding area FA of the first area AA1 is folded with respect to the folding axis FX, the display panel DP may be folded.

The display panel DP may include a plurality of pixels PX, a plurality of scan lines SL1 to SLm, a plurality of data lines DL1 to DLn, a plurality of light emission lines EL1 to ELm, first and second control lines CSL1 and CSL2, a power line PL, a plurality of connection lines CNL, and a plurality of pads PD. The pixels PX may be arranged in the display area DA and may be connected to the scan lines SL1 to SLm, the data lines DL1 to DLn, and the light emission lines EL1 to ELm.

The scan driver SDV and the light emission driver EDV may be disposed in the non-display area NDA. The scan driver SDV and the light emission driver EDV may be disposed in the non-display area NDA to be respectively adjacent to both sides of the first area AA1, which are opposite to each other in the second direction DR2. The data driver DDV may be disposed in the second area AA2. The data driver DDV may be manufactured in an integrated circuit chip form and may be mounted on the second area AA2.

The scan lines SL1 to SLm may extend in the second direction DR2 and may be connected to the scan driver SDV. The data lines DL1 to DLn may extend in the first direction DR1 and may be connected to the data driver DDV via the bending area BA. The data driver DDV may be connected to the pixels PX through the data lines DL1 to DLn. The light emission lines EL1 to ELm may extend in the second direction DR2 and may be connected to the light emission driver EDV.

The power line PL may extend in the first direction DR1 and may be disposed in the non-display area NDA. The power line PL may be disposed between the display area DA and the light emission driver EDV. The power line PL may extend to the second area AA2 via the bending area BA. When viewed in the plane, the power line PL may extend toward a lower end of the second area AA2. The power line PL may receive a driving voltage.

The connection lines CNL may extend in the second direction DR2 and may be arranged in the first direction DR1. The connection lines CNL may be connected to the power line PL and the pixels PX. The driving voltage may be applied to the pixels PX through the power line PL and the connection lines CNL connected to the power line PL.

The first control line CSL1 may be connected to the scan driver SDV and may extend toward the lower end of the second area AA2 via the bending area BA. The second control line CSL2 may be connected to the light emission driver EDV and may extend toward the lower end of the second area AA2 via the bending area BA. The data driver DDV may be disposed between the first control line CSL1 and the second control line CSL2.

When viewed in the plane, the pads PD may be arranged adjacent to the lower end of the second area AA2. The data driver DDV, the power line PL, the first control line CSL1, and the second control line CSL2 may be connected to the pads PD.

The data lines DL1 to DLn may be connected to corresponding pads PD through the data driver DDV. As an example, the data lines DL1 to DLn may be connected to the data driver DDV, and the data driver DDV may be connected to the pads PD corresponding to the data lines DL1 to DLn.

Although not shown in figures, the pads PD may be connected to a printed circuit board, and the timing controller T-CON and the voltage generator VG illustrated in FIG. 8 may be disposed on the printed circuit board. The timing controller T-CON may be manufactured to include one or more integrated circuit chips and may be mounted on the printed circuit board. The timing controller T-CON and the voltage generator VG may be connected to the pads PD through the printed circuit board.

The scan control signal (the first control signal CS1 illustrated in FIG. 8) may be provided to the scan driver SDV through the first control line CSL1. The light emission control signal (the third control signal CS3 illustrated in FIG. 8) may be provided to the light emission driver EDV through the second control line CSL2. The data control signal (the second control signal CS2 illustrated in FIG. 8) may be provided to the data driver DDV.

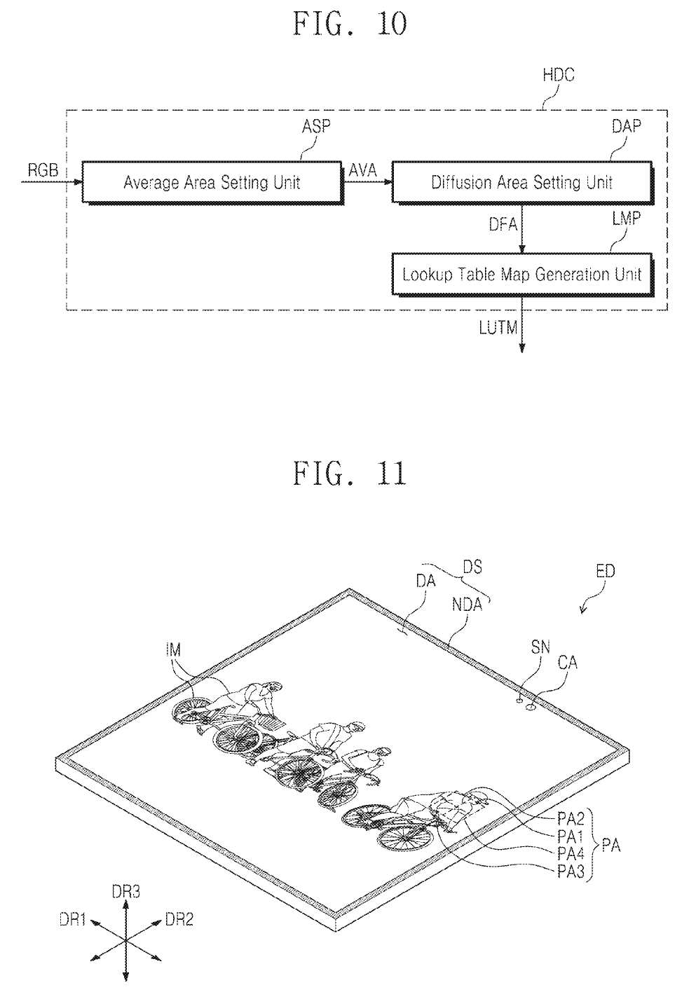

FIG. 10 is a block diagram of the heat generation data calculation unit shown in FIG. 8.

Referring to FIG. 10, the heat generation data calculation unit HDC may calculate heat generation temperature values that may be generated in the pixels PX by images displayed in the display area DA. For this operation, the heat generation data calculation unit HDC may include an average area setting unit ASP, a diffusion area setting unit DAP, and a lookup table map generation unit LMP.

The average area setting unit ASP may receive the image signals RGB. The image signals RGB may have grayscales to be provided to the pixels PX. In addition, the image signals RGB may include position information corresponding to the positions of the pixels PX. That is, the image signals RGB may be provided to correspond to the pixels PX, respectively.

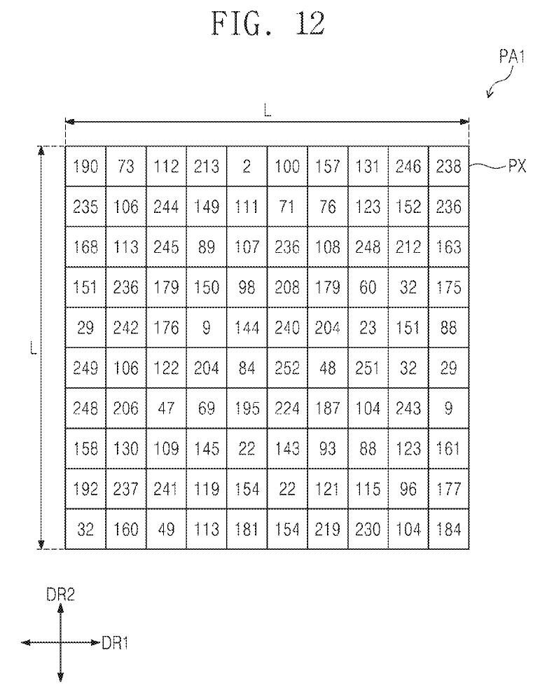

The average area setting unit ASP may group the pixels PX into a plurality of pixel areas PA (hereinafter, shown in FIG. 11). For example, a position map of the pixels PX may be confirmed through the image signals RGB. Based on the position map of the pixels PX, the average area setting unit ASP may set the pixel areas PA, and each of the pixel areas PA may include some pixels PX among the pixels PX.

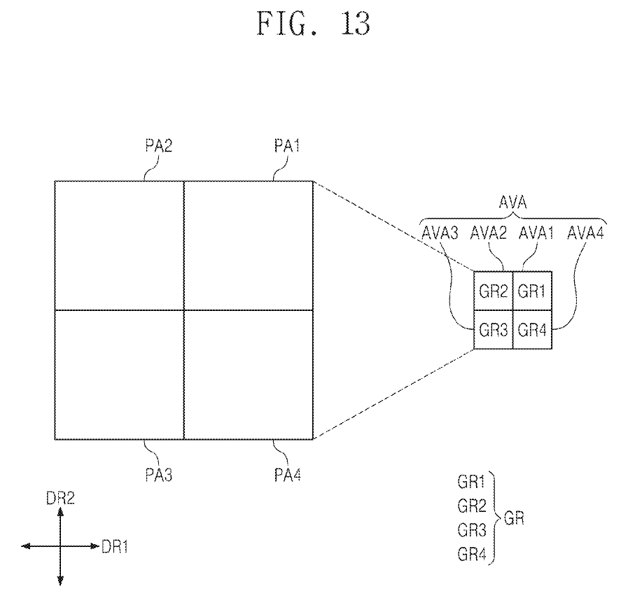

The average area setting unit ASP may set the pixel areas PA to a plurality of average areas AVA (hereinafter, shown in FIG. 13). The average areas AVA may have average grayscales of the pixel areas PA, respectively. The average area setting unit ASP may provide the average areas AVA to the diffusion area setting unit DAP.

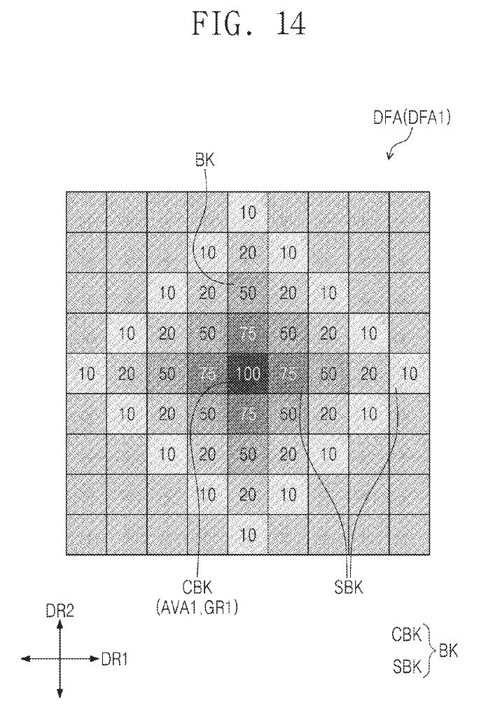

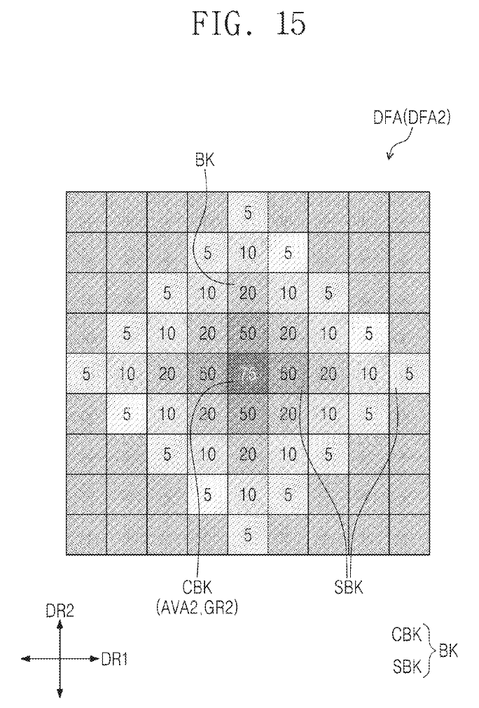

The diffusion area setting unit DAP may set a plurality of diffusion areas DFA (hereinafter, shown in FIGS. 14-16). Each of the diffusion areas DFA may include a plurality of blocks. The blocks of each of the diffusion areas DFA may be disposed to correspond to some average areas AVA among the average areas AVA.

The diffusion area setting unit DAP may set temperature values of the blocks of the diffusion areas DFA based on average grayscales of the average areas AVA. The diffusion area setting unit DAP may provide the diffusion areas DFA to the lookup table map generation unit LMP.

The lookup table map generation unit LMP may match the diffusion areas DFA to the average areas AVA and sum the temperature values of the blocks of the diffusion areas DFA overlapping each other. The lookup table map generation unit LMP may generate the lookup table map LUTM and store the summed temperature values of the blocks in the lookup table map LUTM. Temperature values corresponding to the average areas AVA may be stored in the lookup table map LUTM.

The lookup table map generation unit LMP may output the lookup table map LUTM. The timing controller T-CON may compensate for the image data DATA by using the lookup table map LUTM.

More detailed operations of the average area setting unit ASP, the diffusion area setting unit DAP, and the lookup table map generation unit LMP will be described in more detail below with reference to the drawings.

The heat generation calculation unit HDC may be implemented by hardware, firmware, software, or a combination thereof. For example, the hardware may include one or more integrated circuit chips (IC’s).

FIG. 11 is a view exemplarily illustrating images displayed in the display area of the electronic device.

Referring to FIG. 11, the images IM may be displayed in the display area DA of the electronic device ED. The images IM may include not only objects displayed in the display area DA, but also a background image around the objects.

The display area DA may be divided into a plurality of pixel areas PA. The pixel areas PA may include first to fourth pixel areas PA1, PA2, PA3, and PA4 adjacent to each other and arranged in two rows and two columns. As an example, although four first to fourth pixel areas PA1, PA2, PA3, and PA4 adjacent to each other are shown in FIG. 11, substantially, the display area DA may be divided into more pixel areas PA. The first to fourth pixel areas PA1, PA2, PA3, and PA4 may be sequentially arranged in a counterclockwise direction.

The image IM may be divided according to the pixel areas PA. The pixel areas PA may have a rectangular shape. Therefore, the images IM displayed in the display area DA may be divided into mosaic shapes according to the pixel areas PA.

FIG. 12 is a view specifically illustrating the first pixel area shown in FIG. 11.

Referring to FIGS. 8, 10, and 12, the average area setting unit ASP may set the first pixel area PA1 including some pixels PX among the m×n pixels PX shown in FIG. 8. For example, the first pixel area PA1 may include pixels PX arranged in L rows and L columns. That is, the first pixel area PA1 includes L×L pixels PX and may have a rectangular shape. L is a natural number and may be less than m and n.

Although a structure of the first pixel area PA1 has been described as an example, each of the second, third, and fourth pixel areas PA2, PA3, and PA4 may also be set to include pixels PX arranged in L rows and L columns. Therefore, the average area setting unit ASP may set the first to fourth pixel areas PA1 to PA4, each of which include some pixels PX among the m×n pixels PX.

The image signals RGB may be provided to the pixels PX, and the image signals RGB may include grayscales to be provided to the pixels PX. The numerical values described in the pixels PX shown in FIG. 12 may represent grayscales of the pixels PX. Although not illustrated, the pixels PX of each of the second to fourth pixel areas PA2 to PA4 may also have grayscales.

FIG. 13 is a view illustrating first to fourth average areas corresponding to the first to fourth pixel areas shown in FIG. 11.

Referring to FIGS. 10, 11, and 13, the average area setting unit ASP may calculate the average grayscales GR of the pixel areas PA based on the grayscales of the image signals RGB. The average grayscales GR may include first to fourth average grayscales G1 to GR4 corresponding to the first to fourth pixel areas PA1 to PA4. The average area setting unit ASP may calculate the first to fourth average grayscales GR1 to GR4 of the first to fourth pixel areas PA1 to PA4 based on grayscales of the image signals RGB.

Each of the first to fourth average grayscales GR1 to GR4 may be defined as an average value of grayscales of pixels PX of a corresponding pixel area PA among the first to fourth pixel areas PA1 to PA4. For example, the first average grayscale GR1 of the first pixel area PA1 may be determined as an average value of grayscales of the pixels PX of the first pixel area PA1 shown in FIG. 12.

In the same manner, the second average grayscale GR2 of the second pixel area PA2 may be determined as an average value of grayscales of the pixels PX of the second pixel area PA2. In addition, the third average grayscale GR3 of the third pixel area PA3 may be determined as an average value of the grayscales of the pixels PX of the third pixel area PA3, and the fourth average grayscale GR4 of the fourth pixel area PA4 may be determined as an average value of the grayscales of the pixels PX of the fourth pixel area PA4.

The average areas AVA may include first to fourth average areas AVA1 to AVA4 corresponding to the first to fourth pixel areas PA1 to PA4, respectively. The average area setting unit ASP may set the first to fourth pixel areas PA1 to PA4 to the first to fourth average areas AVA1 to AVA4 having the first to fourth average grayscales GR1 to GR4 of the first to fourth pixel areas PA1 toPA4, respectively.

The first to fourth average areas AVA1 to AVA4 may be disposed to correspond to the first to fourth pixel areas PA1 to PA4. Therefore, the first to fourth average areas AVA1 to AVA4 may be adjacent to each other and disposed in two rows and two columns. The first to fourth average areas AVA1 to AVA4 may be sequentially disposed in a counterclockwise direction.

Although the first to fourth pixel areas PA1 to PA4 have been exemplarily described, the average areas AVA corresponding to the other pixel areas PA may also be set in the above-described manner. The average area setting unit ASP may provide the average areas AVA to the diffusion area setting unit DAP. The average areas AVA may be mosaiced into a grayscale image corresponding to the average grayscales GR and provided to the diffusion area setting unit DAP.

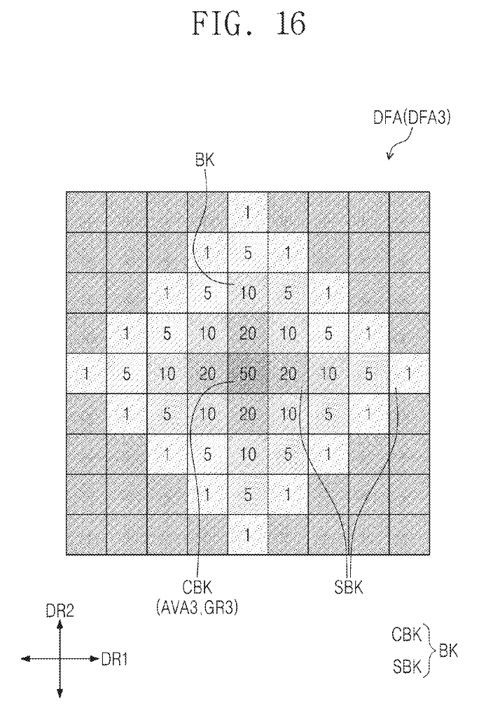

FIG. 14 is a view illustrating a first diffusion area corresponding to the first average area shown in FIG. 13. FIG. 15 is a view illustrating a second diffusion area corresponding to the second average area shown in FIG. 13. FIG. 16 is a view illustrating a third diffusion area corresponding to the third average area shown in FIG. 13.

Referring to FIGS. 14, 15, and 16, the diffusion area setting unit DAP may set a plurality of diffusion areas DFA, and each of the diffusion areas DFA may include a plurality of blocks BK. The diffusion areas DFA may include first, second, and third diffusion areas DFA1, DFA2, and DFA3 corresponding to the first, second, and third average areas AVA1, AVA2, and AVA3, respectively.

As an example, the first, second, and third diffusion areas DFA1, DFA2, and DFA3 are illustrated, but the diffusion area setting unit DAP may also set other diffusion areas DFA corresponding to other average areas AVA. Blocks BK in which numbers are written in FIGS. 14, 15, and 16, may be the first, second, and third diffusion areas DFA1, DFA2, and DFA3.

Each of the diffusion areas DFA may be set to be larger than each of the average areas AVA. Each of the blocks BK of the diffusion areas DFA may have the same size as each of the average areas AVA. Therefore, a size of each of the diffusion areas DFA including the blocks BK may be larger than that of each of the average areas AVA.

For example, the first diffusion area DFA1 corresponding to the first average area AVA1 may be set to be larger than the first average area AVA1. In addition, the second diffusion area DFA2 corresponding to the second average area AVA2 may be set to be larger than the second average area AVA2, and the third diffusion area DFA3 corresponding to the third average area AVA3 may be set to be larger than the third average areaAVA3.

The blocks BK of each of the first, second, and third diffusion areas DFA1, DFA2, and DFA3 may include a center block CBK and a plurality of peripheral blocks SBK disposed around the center block CBK. The diffusion area setting unit DAP may determine the blocks BK of each of the diffusion areas DFA by setting each of the average areas AVA as the center block CBK and arranging a predetermined number of peripheral blocks SBK around the center block CBK. Thus, the center blocks CBK may correspond to the average areas AVA, respectively.

For example, the center block CBK of the first diffusion area DFA1 may correspond to the first average area AVA1. The peripheral blocks SBK of the first diffusion area DFA1 may correspond to the average areas AVA disposed around the first average area AVA1. Substantially, a position of the center block CBK of the first diffusion area AVA1 may be set to a position of the first average area AVA1, and positions of the peripheral blocks SBK of the first diffusion area DFA1 may be set as positions of the average areas AVA disposed around the first average area AVA1.

Blocks BK of the second diffusion area DFA2 and blocks BK of the third diffusion area DFA3 may be set in the same manner. The number of the peripheral blocks SBK disposed around the center block CBK may be preset.

The diffusion area setting unit DAP may set temperature values of the blocks BK of the first, second, and third diffusion areas DFA1, DFA2, and DFA3 based on the first, second, and third average grayscales GR1, GR2, and GR3. For example, a temperature value of the center block CBK of the first diffusion area DFA1 may be set to a temperature value corresponding to the first average grayscale GR1 of the first average area AVA1. As the grayscale increase, the temperature value may be set higher. In addition, temperature values of the peripheral blocks SBK of the first diffusion area DFA1 may be set to be gradually lower than the temperature value of the center block CBK as a distance from the center block CBK increases.

The peripheral blocks SBK may be defined as a heat diffusion area according to the temperature of the center block CBK. As heat of the center block CBK according to the temperature of the center block BCK diffuses to the periphery, the temperatures of the peripheral blocks SBK may gradually decrease as the distance from the center block CBK increases. Therefore, when the center block CBK of the first diffusion area DFA1 has a predetermined temperature value according to the first average grayscale GR1 of the first average area AVA1, the peripheral blocks SBK of the first diffusion area DFA1 may have temperature values that are gradually lower than the center block CBK as the distance from the center block CBK increases.

The numerical values in FIG. 14 may be values obtained by converting the temperature values into specific numerical values. For convenience of description of the calculation operation, the temperature values are shown as the specific numerical values. For example, in FIG. 14, the numerical value 100 may represent 5°C, the numerical value 75 may represent 3.75°C, a numerical value 50 may represent 2.5°C, 20 may represent 1°C, and a numerical value 10 may mean 0.5°C. Thus, the numerical values shown in FIG. 14 may represent a relative proportion of the temperature values. However, this is an exemplary description, the numerical values shown in FIG. 14 may represent various temperature values.

As an example, the temperature values of the blocks BK of the first diffusion area DFA1 have been described, but the temperature values of blocks BK of the second diffusion area DFA2 and the temperature values of block BK of the third diffusion area DFA3 shown in FIGS. 15 and 16 may be set in the same manner. The diffusion area setting unit DAP may provide the set diffusion areas DFA to the lookup table map generation unit LMP.

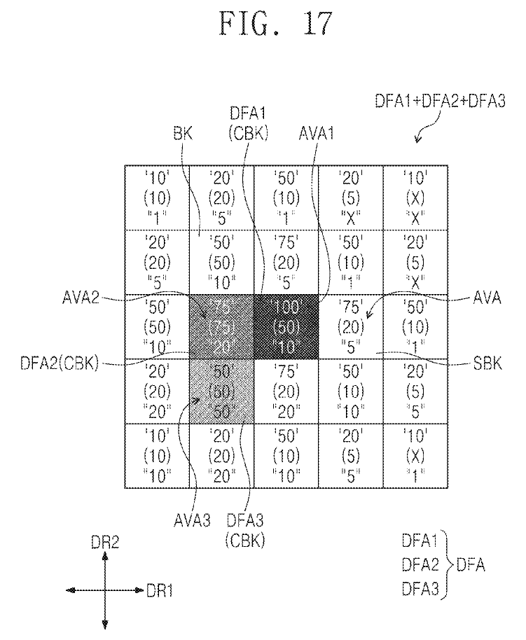

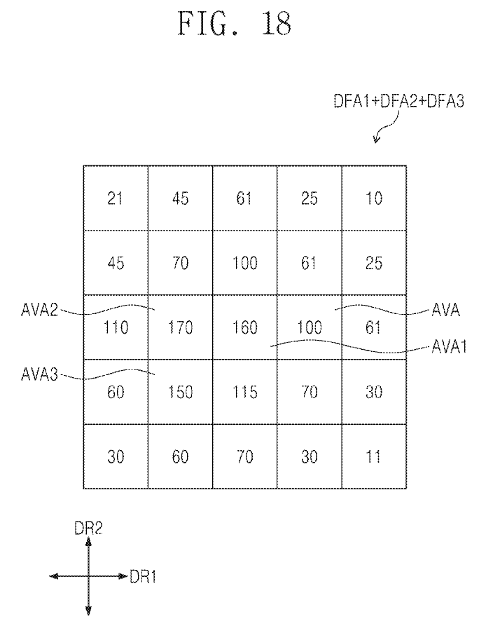

FIG. 17 is a view illustrating a summing operation of temperature values of the first, second, and third diffusion areas shown in FIGS. 14-16. FIG. 18 is a view illustrating summed values of the temperature values shown in FIG. 17.

Referring to FIGS. 14-17, values in ‘ ’ may represent the temperature values of the blocks BK of the first diffusion area DFA1 shown in FIG. 14, values in ( ) may represent the temperature value of the blocks BK of the second diffusion area DFA2 shown in FIG. 15, and the values in “ “ may represent the temperatures value of the blocks BK of the third diffusion area DFA3 shown in FIG. 16.

The lookup table map generation unit LMP may match the blocks BK of the first, second, and third diffusion areas DFA1, DFA2, and DFA3 to the average areas AVA. For example, the lookup table map generation unit LMP may match the center blocks CBK to the corresponding average areas AVA.

Specifically, the lookup table map generation unit LMP may overlap the center block CBK of the first diffusion area DFA1 with the first average area AVA1, overlap the center block CBK of the second diffusion area DFA2 with the second average area AVA2, and overlap the center block CBK of the third diffusion area DFA3 with the third average area AVA3.

In this case, the peripheral blocks SBK of the first diffusion area DFA1 may overlap the average areas AVA disposed around the first average area AVA1. In addition, the peripheral blocks SBK of the second diffusion area DFA2 may overlap the average areas AVA disposed around the second average area AVA2. In addition, the peripheral blocks SBK of the third diffusion area DFA3 may overlap the average areas AVA disposed around the third average area AVA3. Therefore, the blocks BK of the first, second, and third diffusion areas DFA1, DFA2, and DFA3 may overlap each other.

Referring to FIGS. 17 and 18, the lookup table map generation unit LMP may sum the temperature values of the blocks BK overlapping each other. For example, the center block CBK of the first diffusion area DFA1, the block BK disposed on the right side of the center block CBK of the second diffusion area DFA2, and block BK spaced to the right and upper from the center block CBK of the third diffusion area DFA3 may be matched to the first average area AVA1 and overlap each other.

Since the temperature values of the blocks BK overlapping each other in the first average area AVA1 are 100, 50, and 10, the summed temperature value may be 160. The lookup table map generation unit LMP may match the summed temperature value 160 to the first average area AVA1 and store the summed temperature value 160 matched to the first average area AVA1 in the lookup table map LUTM. Therefore, a heat generation data of the first average area AVA1 may be calculated as 160.

In addition, the center block CBK of the second diffusion area DFA2, the block BK disposed on the left side of the center block CBK of the first diffusion area DFA1, and the block BK disposed on the upper side of the third diffusion area DFA3 may be matched to the second average area AVA2 and overlap each other.

Since the temperature values of the blocks BK overlapping each other in the second average area AVA2 are 75, 75, and 20, the summed temperature value may be 170. The lookup table map generation unit LMP may match the summed temperature value 170 to the second average area AVA2 and store the summed temperature value 170 matched to the second average area AVA2 in the lookup table map LUTM. Therefore, a heat generation data of the second average area AVA2 may be calculated to be 170.

The temperature values of the other overlapping blocks BK may also be summed in the same manner. For example, the summed temperature values may be matched to the average areas AVA and stored the summed temperature values matched to the average areas AVA in the lookup table map LUTM. That is, the lookup table map generation unit LMP may match the summed temperature values to the average areas AVA, store the summed temperature values matched to the average areas AVA in the lookup table map LUTM, and output the lookup table mapping LUTM.

The timing controller T-CON described above may compensate for the image data DATA by using the lookup table map LUTM. For example, as the temperature increases, the elements of the pixels PX may deteriorate more. Therefore, luminance corresponding to the image data DATA may not generated, and lower luminance may be generated. As the temperature increases, the timing controller T-CON may increase and output grayscales of the image data DATA.

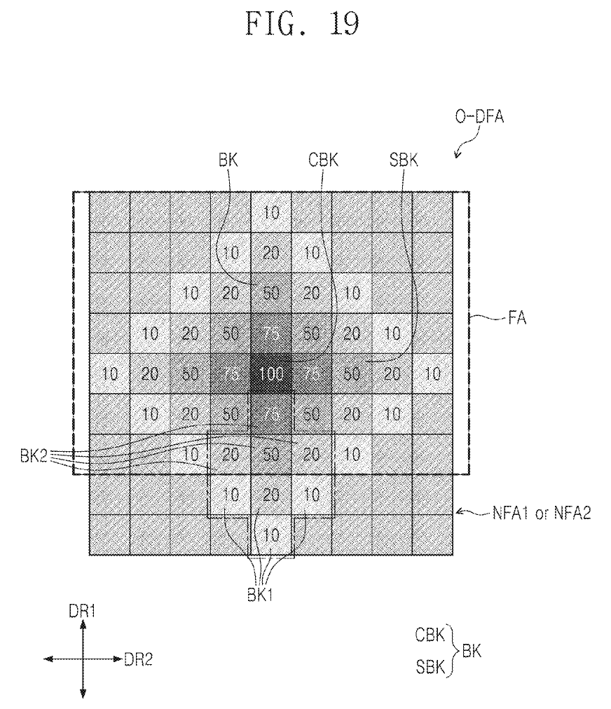

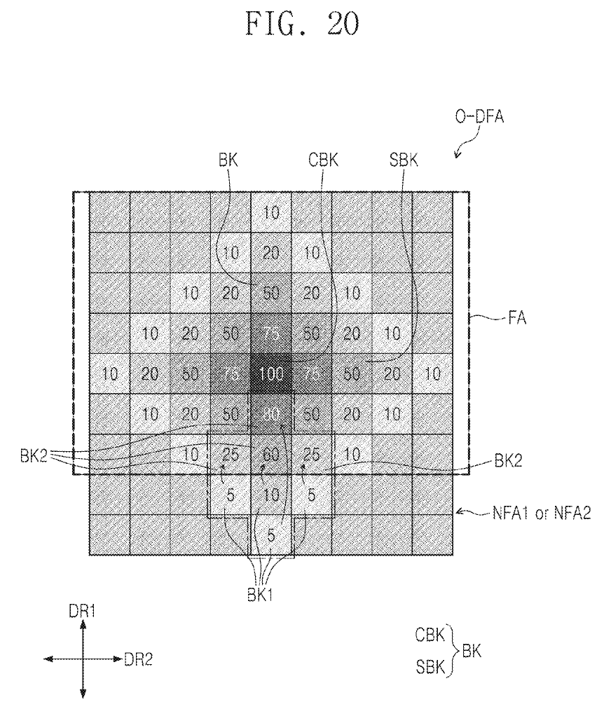

FIGS. 19 and 20 are views illustrating an operation of the diffusion area setting unit when the center block is disposed in the folding area of the display panel.

The operation described in FIGS. 14-16 may be an operation of the diffusion area setting unit DAP when the center block CBK is disposed in the non-folding area NDA.

As an example, in FIGS. 19 and 20, the folding area FA of the display panel DP is shown by a dotted line.

Referring to FIG. 19, the diffusion area DFA set in the diffusion area setting unit DAP may be continuously disposed in the folding area FA and the first non-folding area NFA1 (or the second non-folding area NFA2). In addition, the center block CBK of the diffusion area DFA may be disposed in the folding area FA. In this case, the diffusion area setting unit DAP may perform an additional calculation operation on the diffusion area DFA.

As described above in FIG. 6, some of the heat generated in the folding area FA may diffuse to the first and second non-folding areas NFA1 and NFA2, but the remaining heat may not diffuse to the first and second non-folded areas NFA1 and NFA and remain in the foldable area FA.

A ratio of heat that does not diffuse from the folding area FA to the first and second non-folding areas NFA1 and NFA2 is defined as a reduction rate, hereinafter, and the reduction rate may be set by an experimental test in advance. The diffusion area DFA disposed in the folding area FA and the first non-folding area NFA1 (or the second non-folding area NFA2) may be defined as an overlapping diffusion area O-DFA.

Referring to FIGS. 19 and 20, among blocks BK of the overlapping diffusion area O-DFA, blocks BK disposed in the first non-folding area NFA1 (or the second non-folding area NFA2) may be defined as first blocks BK1. Among the blocks BK of the overlapping diffusion area O-DFA, blocks BK disposed in the folding area FA to be symmetrical to the first blocks BK1 may be defined as second blocks BK2. The second blocks BK2 may be disposed to be respectively symmetrical to the first blocks BK1 with respect to a boundary between the folding area FA and the first non-folding area NFA1 (or the second non-folding area NFA2).

Referring to FIG. 20, the diffusion area setting unit DAP may reduce temperature values of the first blocks BK1 among the blocks BK of the overlapping diffusion area O-DFA to a predetermined reduction rate. As an example, the reduction rate may be set to 50%, but is not limited thereto, and the numerical value of the reduction rate may be variously set. Depending on the reduction rate, the temperature values of the first blocks BK1 may be reduced from 20 to 10 and from 10 to 5.

The diffusion area setting unit DAP may increase temperature values of the second blocks BK2 disposed in the folding area FA. The temperature value of each of the second blocks BK2 may be increased by a reduced temperature value of the symmetrical first block BK1 among the first blocks BK1.

For example, as shown in an arrow direction in FIG. 20, the reduced temperature values of the first blocks BK1 may be added to the temperature values of the second blocks BK2 that are symmetrical to the first blocks BK1, respectively. Thus, the temperature values of the second blocks BK2 may be increased from 20 to 25, from 50 to 60, and from 75 to 80. Thereafter, an operation of summing the temperature values of the blocks BK of the diffusion areas DFA that overlap with each other may be performed as described above.

As a result, in an embodiment of the present disclosure, the heat generation data calculated based on the grayscales may be calculated to be suitable for the non-folding areas NFA1 and NFA2 and the folding area FA of the display panel DP.

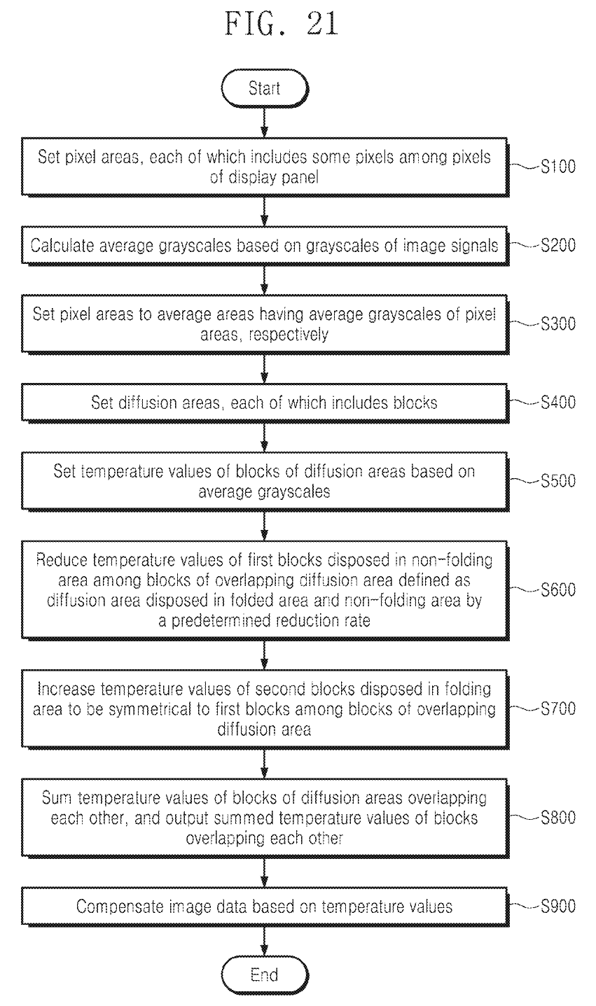

FIG. 21 is a flowchart illustrating a method of driving a display according to the embodiment of the present disclosure.

Referring to FIG. 21, in step S100, the pixel areas, each of which includes some pixels PX among the pixels PX of the display panel DP, may be set. In step S200, the average grayscales GR may be calculated based on the grayscales of the image signals RGB. Each of the average grayscales GR may be defined as an average value of grayscales of the pixels PX of the corresponding pixel area PA among the pixel areas PA.

In step S300, the pixel areas PA may be set to the average areas AVA having the average grayscales GR of the pixel areas PA, respectively. In step S400, the diffusion areas DFA, each of which includes the plurality of blocks BK may be set. In step S500, the temperature values of the blocks BK of the diffusion areas DFA may be set based on the average grayscales GR.

In step S600, the temperature values of the first blocks BK1 disposed in the non-folding area (the first non-folding area NFA1 or the second non-folding area NFA2) among the blocks BK of the overlapping diffusion area O-DFA defined as the diffusion area DFA disposed in the folded area FA and the non-folding area (the first non-folding area NFA1 or the second non-folding area NFA2) may be reduced by a predetermined reduction rate.

In step S700, the temperature values of the second blocks BK2 disposed in the folding area FA so as to be symmetrical to the first blocks BK1, among the blocks BK of the overlapping diffusion area O-DFA may be increased. The temperature value of each of the second blocks BK2 may increase by the reduced temperature value of the symmetrical first block BK1 among the first blocks BK1.

In step S800, the temperature values of the blocks BK of the diffusion areas DFA overlapping each other may be summed, and the summed temperature values of the blocks BK may be output. For example, the blocks BK of the diffusion areas DFA may be matched to the average areas AVA, and the temperature values of the blocks BK of the diffusion areas DFA overlapping each other may be summed. The summed temperature values may be matched to the average areas AVA, the summed temperature values matched to the average areas AVA may be stored in the lookup table map LUTM, and the lookup table map LUTM may be output. In step S900, based on the temperature values, the image data DATA may be compensated.

According to an embodiment of the present disclosure, the temperature values of the diffusion area may be set based on the average temperature of the average area in the non-folding area. In addition, after the diffusion area is set based on the average temperature of the average area in the folding area, the temperature values of the diffusion area of the folding area may be increased by the reduction rate defined as the rate of heat transfer that does not diffuse into the non-folding area. Therefore, the heat generation data is calculated to be suitable for the non-folding area and the folding area of the display panel, so that the compensation operation for the pixels may be normally performed.

In the above, description has been made with reference to embodiments of the inventive concept, but those skilled or of ordinary skill in the art may understand that various modifications and changes may be made to the inventive concept insofar as such modifications and changes do not depart from the spirit and technical scope of the inventive concept set forth in the claims to be described later.

Therefore, the technical scope of the inventive concept is not to be limited to the contents stated in the detailed description of the specification, but should be determined by the claims.

What is claimed is:

1. A display device comprising:
a display panel including a plurality of pixels; and
a timing controller that controls driving of the pixels and includes a heat generation data calculation unit,
wherein the heat generation data calculation unit includes:
an average area setting unit that sets a plurality of pixel areas, each of which includes some pixels among the pixels, and sets the pixel areas to a plurality of average areas having average grayscales of the pixel areas, respectively;
a diffusion area setting unit that sets a plurality of diffusion areas, each of which includes a plurality of blocks, and sets temperature values of the blocks of the diffusion areas based on the average grayscales; and
a lookup table map generation unit that sums the temperature values of the blocks of the diffusion areas overlapping each other to produce summed temperature values of the blocks overlapping each other, and outputs the summed temperature values,
wherein a diffusion area disposed in a folding area and a non-folding area of the display panel is defined as an overlapping diffusion area, and
wherein the diffusion area setting unit reduces temperature values of first blocks disposed in the non-folding areas among blocks of the overlapping diffusion area by a predetermined reduction rate.

2. The display device of claim 1, wherein the diffusion area setting unit increases temperature values of second blocks disposed in the folding area so as to be symmetrical to the first blocks among the blocks of the overlapping diffusion area, and
wherein the second blocks are arranged to be respectively symmetrical to the first blocks with respect to a boundary between the folding area and the non-folding area.

3. The display device of claim 2, wherein a temperature value of each of the second blocks increases by a reduced temperature value of a symmetrical first block among the first blocks.

4. The display device of claim 1, wherein a center block among the blocks of the overlapping diffusion area is disposed in the folding area.

5. The display device of claim 1, wherein each of the pixel areas includes pixels arranged in L rows and L columns and has a rectangular shape, wherein L is a natural number.

6. The display device of claim 1, wherein the timing controller receives image signals to be provided to the pixels,
wherein the average area setting unit calculates the average grayscales based on grayscales of the image signals, and
wherein each of the average grayscales is defined as an average value of grayscales of pixels of a corresponding pixel area among the pixel areas.

7. The display device of claim 1, wherein each of the diffusion areas has a size larger than that of each of the average areas.

8. The display device of claim 7, wherein each of the blocks has the same size as each of the average areas.

9. The display device of claim 1, wherein the blocks of each of the diffusion areas include:
a center block; and
a plurality of peripheral blocks arranged around the central block,
wherein a position of the center block of each of the diffusion areas is set to a position of a corresponding average area among the average areas, and
wherein the peripheral blocks of each of the diffusion areas are set to positions of average areas disposed around the corresponding average area.

10. The display device of claim 9, wherein when the temperature values of the blocks are set based on the average grayscales, a temperature value of the center block of each of the diffusion areas is set to a temperature value corresponding to an average grayscale of the corresponding average area.

11. The display device of claim 10, wherein temperature values of the peripheral blocks of each of the diffusion areas are gradually lower than the temperature value of the central block of each of the diffusion areas as a distance from the center block of each of the diffusion areas increases.

12. The display device of claim 11, wherein the lookup table map generation unit matches the blocks of the diffusion areas to the average areas, sums the temperature values of the blocks of the diffusion areas overlapping each other, matches the summed temperature values to the average areas, and stores the summed temperature value matched to the average areas in a lookup table map, and
wherein the timing controller converts image signals to be provided to the pixels into image data and outputs the image data, and compensates the image data based on the temperature values stored in the lookup table map.

13. A driving method of a display device, the driving method comprising:
setting a plurality of pixel areas, each of which includes some pixels among pixels of a display panel;
setting the pixel areas to a plurality of average areas having average grayscales of the pixel areas, respectively;
setting a plurality of diffusion areas, each of which includes a plurality of blocks;
setting temperature values of the blocks of the diffusion areas based on the average grayscales;
reducing temperature values of first blocks disposed in a non-folding area among blocks of an overlapping diffusion area by a predetermined reduction rate, the overlapping diffusion area defined as a diffusion area disposed in a folding area and the non-folding area of the display panel;
increasing temperature values of second blocks disposed in the folding area to be symmetrical to the first blocks among the blocks of the overlapping diffusion area;
summing temperature values of blocks of the diffusion areas overlapping each other to produce summed temperature values of the blocks overlapping each other;
outputting the summed temperature values of the blocks overlapping each other; and
compensating, based on the temperature values, image data obtained by converting image signals received to be provided to the pixels,
wherein the second blocks are arranged to be respectively symmetrical to the first blocks with respect to a boundary between the folded area and the non-folded area.

14. The driving method of claim 13, wherein a temperature value of each of the second blocks increases by a reduced temperature value of a symmetrical first block among the first blocks.

15. The driving method of claim 13, wherein a center block of the blocks of the overlapping diffusion area is disposed in the folding area.

16. The driving method of claim 13, further comprising calculating the average grayscales based on grayscales of the image signal,
wherein each of the average grayscales is defined as an average value of grayscales of pixels of a corresponding pixel area among the pixel areas.

17. The driving method of claim 13, wherein
each of the diffusion areas has a size larger than that of each of the average areas, and
wherein each of the blocks has the same size as each of the average areas.

18. The driving method of claim 13, wherein the blocks of each of the diffusion areas include:
a center block; and
a plurality of peripheral blocks arranged around the central block,
wherein a position of the center block of each of the diffusion areas is set to a position of a corresponding average area among the average areas,
wherein the peripheral blocks of each of the diffusion areas are set to positions of average areas disposed around the corresponding average area, and
wherein when the temperature values of the blocks are set based on the average grayscales, a temperature value of the center block of each of the diffusion areas is set to a temperature value corresponding to an average grayscale of the corresponding average area, and
wherein temperature values of the peripheral blocks of each of the diffusion areas are gradually lower than the temperature value of the central block of each of the diffusion areas as a distance from the center block of each of the diffusion areas increases.

19. An electronic device comprising:
a processor; and
a display device that receives image signals from the processor and provides images corresponding to the image signals to a user,
wherein the display device includes:
a display panel including a plurality of pixels; and
a timing controller that controls driving of the pixels and includes a heat generation data calculation unit,
wherein the heat generation data calculation unit includes:
an average area setting unit that sets a plurality of pixel areas, each of which includes some pixels among the pixels, and sets the pixel areas to a plurality of average areas having average grayscales of the pixel areas, respectively;
a diffusion area setting unit that sets a plurality of diffusion areas, each of which includes a plurality of blocks, and sets temperature values of the blocks of the diffusion areas based on the average grayscales; and
a lookup table map generation unit that sums temperature values of blocks of the diffusion areas overlapping each other to produce summed temperature values of the blocks overlapping each other, and outputs the summed temperature values,
wherein a diffusion area disposed in a folding area and a non-folding area of the display panel is defined as an overlapping diffusion area, and
wherein the diffusion area setting unit reduces temperature values of first blocks disposed in the non-folding areas among blocks of the overlapping diffusion area by a predetermined reduction rate.
